(19) United States
(12) Patent Application Publication
(10) Pub. No.: US 2008/0293172 A1
(43) Pub. Date: Nov. 27, 2008

(54) Method for manufacturing light emitting diode devices

(76) Inventors: Ming-Shun Lee, Taipei (TW); Shu-Wei Chiu, Chunan Township (TW)

Correspondence Address: TROXELL LAW OFFICE PLLC, SUITE 1404, 5205 LEESBURG PIKE, FALLS CHURCH, VA, 22041, US

(21) Appl. No.: 12/007,051

(22) Filed: Jan. 4, 2008

(30) Foreign Application Priority Data
Jan. 5, 2007 (TW) 096100470

(51) Int. Cl. H01L 33/00

(52) U.S. Cl. 438/27; 438/28; 257/E33.06

(57) ABSTRACT

A method for manufacturing LED devices is disclosed to manufacture vertical LED devices without removing nonconductive substrates. A conductive substrate is formed on the LED epitaxial layer of the nonconductive substrate to form a LED wafer by bonding or electroplating, which is further cut into a plurality of LED sticks with each space layer bonded between every two LED sticks. Secondly, the plurality of LED sticks and space layers are fixed by a fixture while type I semiconductor layer and active layer of the LED epitaxial layer of each LED stick are covered by each space layer. A transparent conductive layer is further formed thereon whereby to electrically connect with the type II semiconductor layer contrary to type I and are further formed with a plurality of electrodes thereon. Finally the said LED sticks are cut to a plurality of LED devices.

### BACKGROUND OF THE INVENTION

(a) Field of the Invention

The invention is related to a method for manufacturing LED devices, especially to a method of manufacturing a vertical LED device without the need to remove the poor heat dissipative non-conductive substrate.

(b) Description of the Prior Art

Since gallium nitride (GaN) has a wide energy intervals (Eg=3.4 eV at room temperature) with a lighting range close to the wavelength of a blue light, it is a very suitable material for short wavelength lighting devices and therefore has become one of the most popular material for developing optoelectronic devices. Although the present technology has been able to grow gallium nitride stably on the sapphire substrate to manufacture short wavelength light emitting diodes (LED), due to poor heat dissipation of sapphire, the reliability of LED is not good.

To overcome the poor heat dissipating problem of sapphire, after the gallium nitride LED expitaxial layer is formed on the sapphire substrate, the gallium nitride LED expitaxial layer is further bonded on a substrate with a better heat dissipation, after that, the sapphire substrate is removed to form the LED device.

FIGS. 1A˜1D are sectional views showing the conventional method for manufacturing gallium nitride LED device. As shown in FIG. 1A, a sapphire substrate 10, on which the gallium nitride LED expitaxial layer 11 is formed, whereof the gallium nitride LED expitaxial layer 11 is comprised of n type gallium nitride layer 12, active layer 13 and p type gallium nitride layer 14. As shown in FIG. 1B, a conductive substrate 16, on which a conductive bonding layer 17 is formed. Secondly, as shown in FIG. 1C, the sapphire substrate 10 and the conductive substrate 16 are bonded. As shown in FIG. 1D, the said sapphire substrate 10 is removed so that one surface of the gallium nitride LED expitaxial layer 11 is exposed, then a plurality of electrodes 18 are formed on the surface of the gallium nitride LED expitaxial layer 11, and lastly it is cut to form a plurality of LED devices. Due to poor heat dissipation of sapphire, the gallium nitride LED expitaxial layer is further bonded with a conductive substrate 16, then the sapphire substrate is removed to make the LED devices have the advantages such as good heat dissipating effect, good anti-static electricity effect and good for large current operation, etc.

However, when separating the gallium nitride LED expitaxial layer 11 and the sapphire substrate 10, the gallium nitride LED expitaxial layer 11 is easily damaged. For example, separating the gallium nitride LED expitaxial layer 11 and the sapphire substrate 10 by impulse laser easily cause the gallium nitride LED expitaxial layer to be deteriorated.

In view of the imperfections of conventional LED devices, the invention discloses a method for manufacturing LED device, whereby the vertical type LED devices with electrodes on the top and bottom surfaces can be formed without the need to remove the poor heat dissipative non-conductive substrate, so that damages to the LED expitaxial layer can be avoided and the sealing procedure can be simplified.

### SUMMARY OF THE INVENTION

One purpose of the invention is to provide a method for manufacturing LED devices without removing the poor heat dissipating non-conductive substrate to avoid damaging the LED epitaxial layer in separating LED epitaxial layer and non-conductive substrate.

Based on the above purpose, the invention discloses a method for manufacturing LED devices without the need to remove non-conductive substrate. A conductive substrate is formed on the LED expitaxial layer with non-conductive substrate by electroplating or bonding method, thereby to form a LED wafer which is cut to a plurality of LED sticks, whereof each space layer is bonded between every two LED sticks, and the row of LED sticks and space layers are fixed by a fixture while the space layer covers the type I semi-conductor layer and active layer. Next, a transparent conductive layer is formed on top of the LED sticks and space layers so that the transparent conductive layer on top of the non-conductive substrate is electrically connected with the type II semi-conductor layer contrary to type I, whereby the subsequent manufacturing process are performed, such as electrodes forming and cutting, etc to manufacture a plurality of LED devices.

### BRIEF DESCRIPTION OF THE DRAWINGS

FIGS. 1A˜1D are the sectional drawings showing a conventional method for manufacturing gallium nitride LED devices.

FIGS. 2A˜2D are the embodying example schematic diagram of the invention showing the method for forming LED wafer.

FIGS. 2E˜2I are the first embodying example schematic diagrams of the invention showing the method for manufacturing LED devices.

FIGS. 3A˜3B are the second embodying example schematic diagrams of the invention showing the method for manufacturing LED devices.

FIGS. 4A˜4B are the embodying example schematic diagrams of the invention showing the method for bonding electrodes on the LED devices.

FIGS. 5A˜5C are the third embodying example schematic diagrams of the invention showing the method for manufacturing LED devices.

FIG. 6 is another embodying example schematic diagram of the invention showing the method for manufacturing high efficient LED devices.

FIGS. 7A˜7D are the embodying example schematic diagrams of the invention showing the method for manufacturing high directive LED devices.

FIG. 8 is a schematic diagram of a high directive LED device.

### DETAILED DESCRIPTION OF THE PREFERRED EMBODIMENTS

Detail embodiments of the invention are described herein, besides the ones described, the invention can also be widely applied in other embodied examples. Therefore, the range of the invention shall be covered by the claims and shall not be limited to the disclosed embodied examples only.

Further, in order to provide a more clearer description for easier understanding the invention, the items shown in the figures are not correspondingly dimensioned, whereof some of the sizes and relevant dimensions may be exaggerated and irreverent details are not shown to maintain the neatness of the figures.

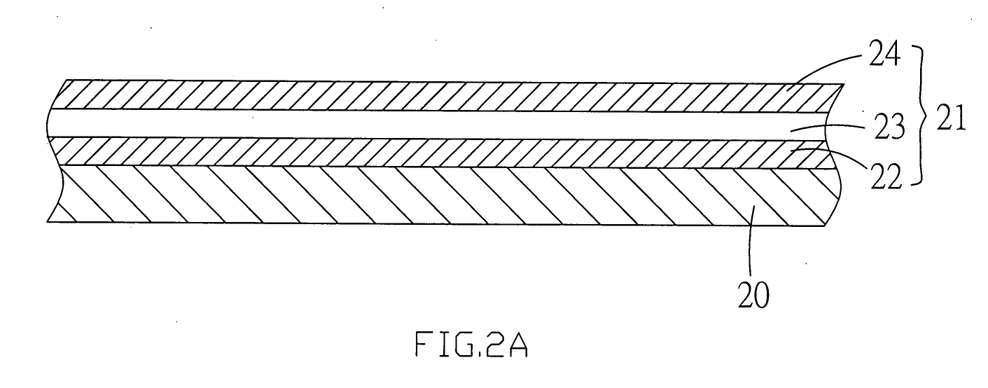

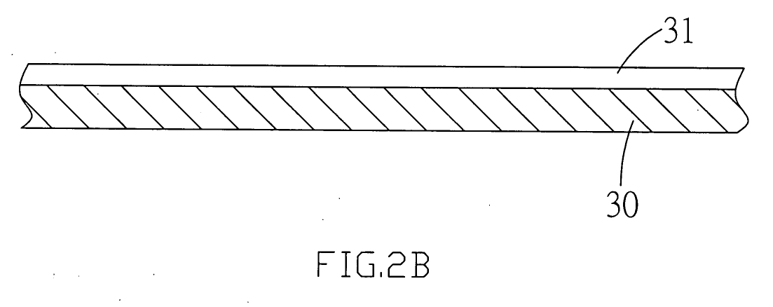

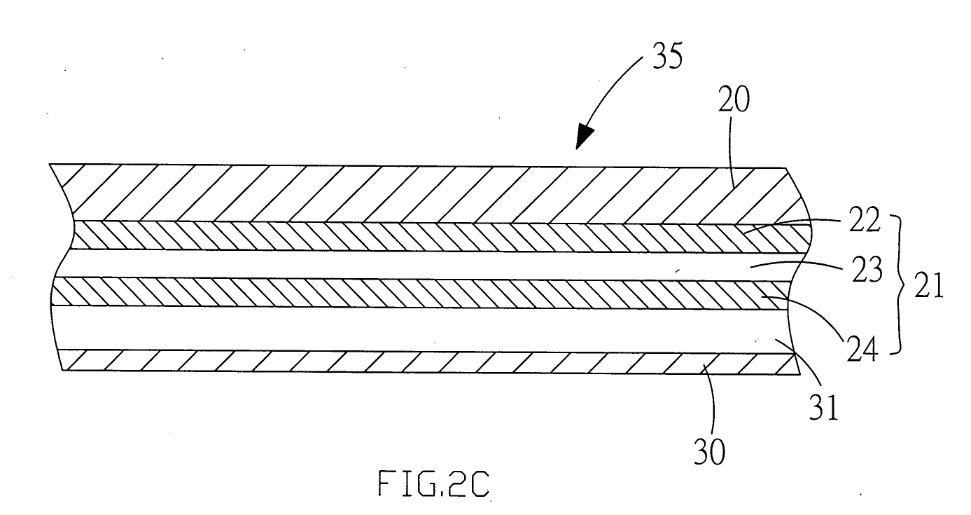

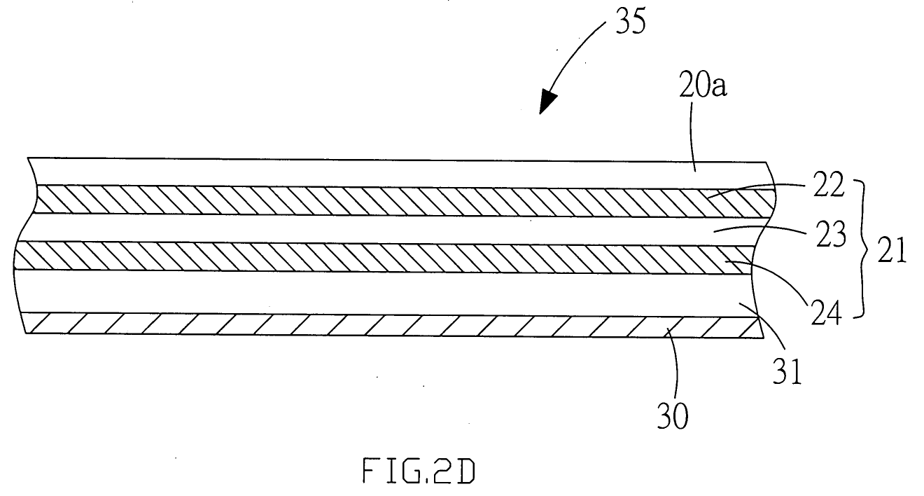

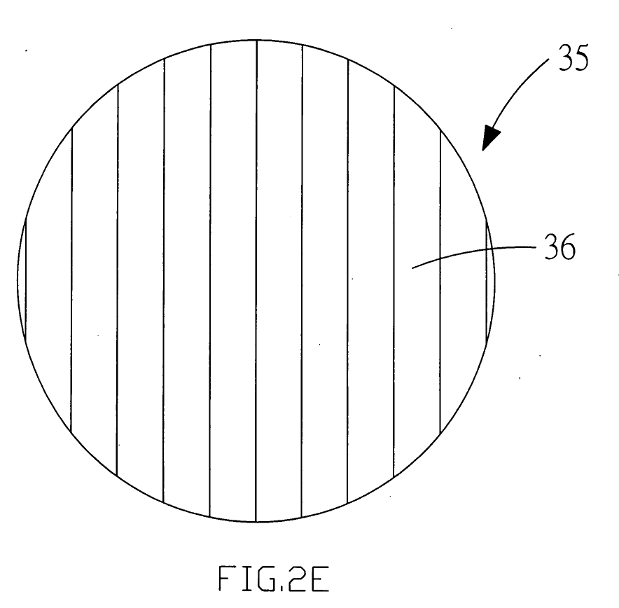

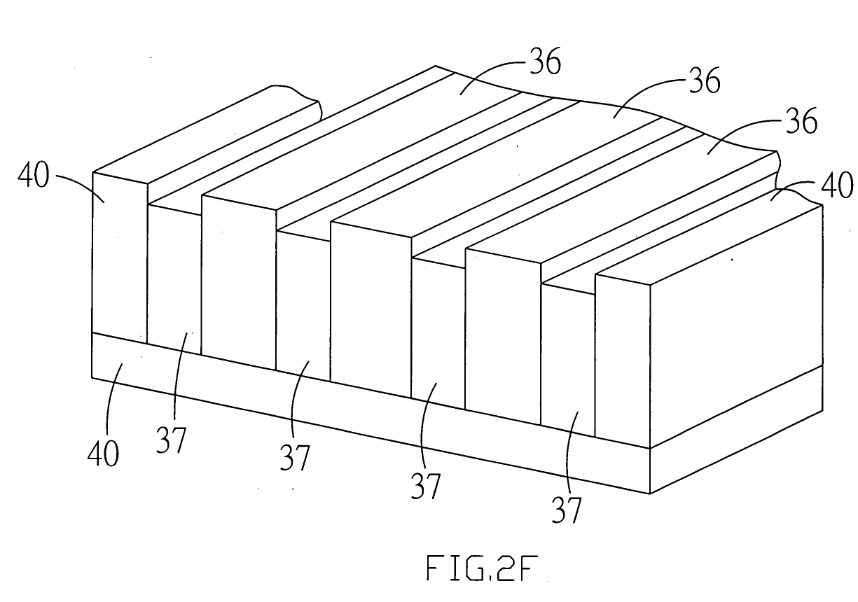

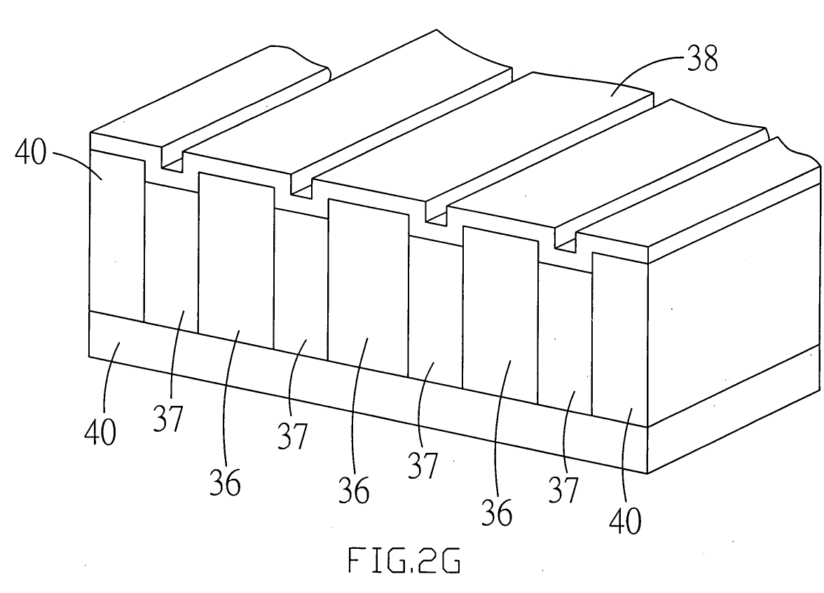

FIGS. 2A˜2D are embodying example schematic diagrams of the invention showing the method for forming LED wafer. Firstly, as shown in FIG. 2A, a LED expitaxial layer 21 is formed on top of a non-conductive substrate 20, whereof the non-conductive substrate 20 is a transparent substrate made of the material such as sapphire. When type I is a n type, the type II is a p type contrary to type I, when type I is a p type, the type II is a n type contrary to type I. Hence, the LED expitaxial layer 21 can be constituted by a n type semi-conductor layer, an active layer and a p type semi-conductor layer in order, or the LED expitaxial layer 21 can be constituted by a p type semi-conductor layer, an active layer and a n type semi-conductor layer. In the embodying example, the LED expitaxial layer can be constituted by a n type gallium nitride layer, an active layer and a p type gallium nitride layer.

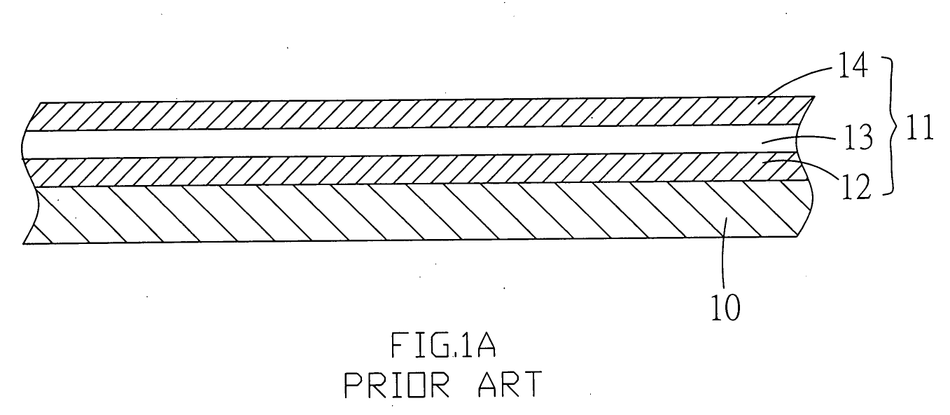

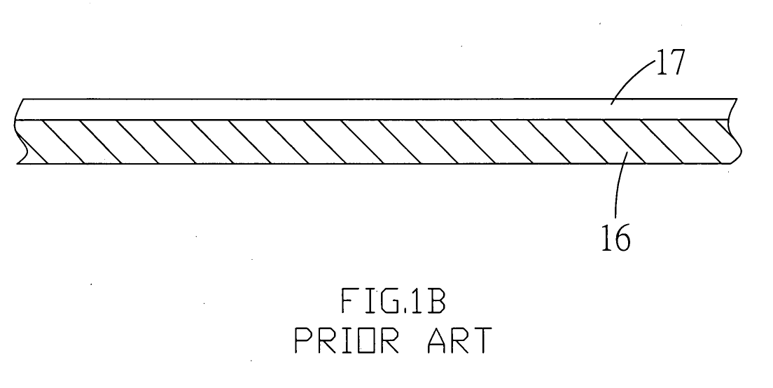

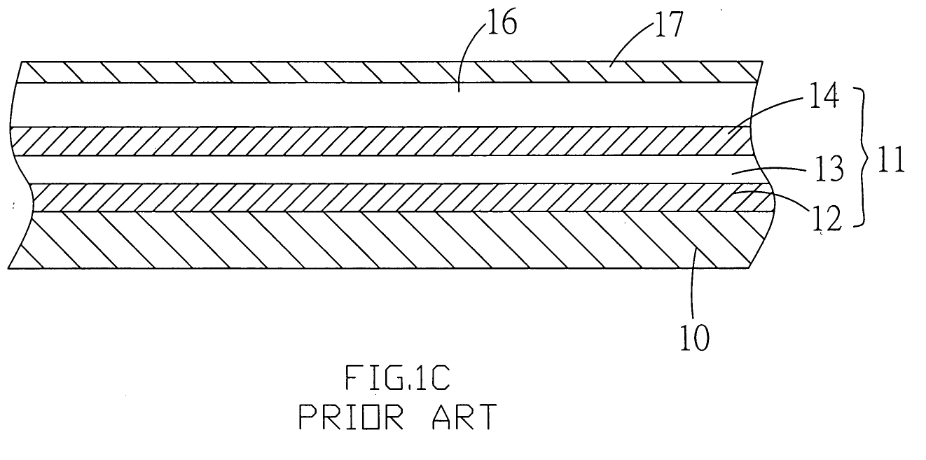

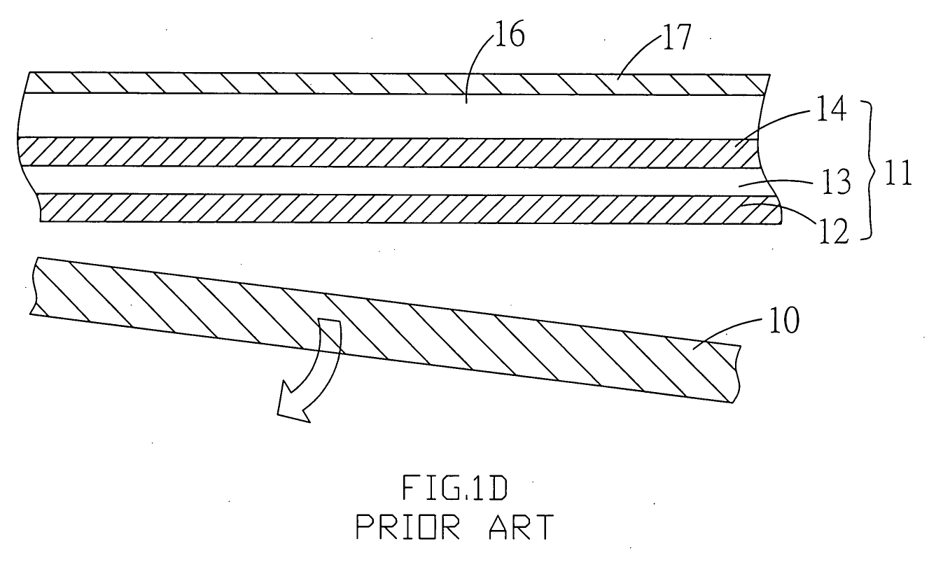

Secondly, a conductive substrate is formed on the LED expitaxial layer 21 of the non-conductive substrate 20 to form a LED wafer. As shown in FIG. 1B, a conductive substrate 30 with a conductive bonding layer 31 is provided, whereof the conductive substrate 30 has a better heat dissipation than the non-conductive substrate 20. Material for conductive substrate 30 can be semi-conductor, metal or alloys. Material for conductive bonding layer 31 can be gold (Au) or gold alloy (Au alloy). Further, a sealing contact layer (not shown in the figure) can also be formed under the conductive substrate 30 for external connection. Thirdly, as shown in FIG. 1C, the non-conductive substrate 20 and conductive substrate 30 can be combined by wafer bonding technologies to form a LED wafer 35, whereof in the embodying example, the wafer bonding technologies can include thermal bonding, thermal compression bonding or thermal ultrasonic bonding, etc.

Further, a conductive substrate can be formed on top of the LED expitaxial layer 21 (not shown in the figure) by electroplating method.

In addition, most of the thickness of non-conductive substrate 20 can be either not reduced or reduced. Thereof, as shown in FIG. 2D, most of the thickness of non-conductive substrate 20 can be reduced by grinding technology to become non-conductive substrate 20a while without exposing the type I conductor layer 22.

FIGS. 2E˜2I are the first embodying example schematic diagram of the invention showing the method for forming LED wafer. Firstly, FIG. 2E shows the top view of the LED wafer 35. As shown in FIG. 2E, the LED wafer 35 is cut to a plurality of LED sticks 36, whereof the cutting technologies can be dicing saw, diamond scriber or laser cutting, etc. Secondly, as shown in FIG. 2F, a plurality of space layers 37, each space layer 37 is bonded between every two LED sticks, whereof the height of each space layer 37 shall completely cover the type II semi-conductor layer 24 and active layer 23 with only the type 1 semi-conductor layer 22 exposed, whereof, the material of space layer can be semi-conductor material such as silicon, or can be ceramic material. Then, the row of LED sticks 36 and space layers 37 are fixed by a fixture 40.

Thirdly, as shown in FIG. 2G, a transparent conductive layer 38 is formed on top of the whole row of LED sticks 36 and space layers 37, so that the transparent conductive layer 38 on the non-conductive substrate 20a is connected with the type I semi-conductor layer 22. Material of the transparent conductive layer 38 can be nickel oxide/Gold (NiO/Au), Indium tin oxide (ITO), zinc oxide (ZnO) or Aluminum zinc oxide (AlZnO), etc. As the type II semi-conductor layer 24 and active layer 23 are covered by the space layer 37, the transparent conductive layer 38 can only be electrically connected with type I semi-conductor layer 22, and the active layer 23 or type II semi-conductor 24 are not connected to avoid causing short-circuit.

Fourthly, as shown in FIG. 2H, the space layers 37 are removed, and the whole row of LED sticks 36 are fixed by a fixture 40, whereby a plurality of type I electrodes 39 are formed on the transparent conductive layer 38 of each of the LED sticks 36, then the LED sticks 36 are cut to a plurality of vertical type LED devices as shown in FIG. 1, whereof in the embodying example, the cutting method can be dicing saw, diamond scriber, or laser cutting. Therefore, the current can be transmitted from type I electrode 39 through the transparent conductive layer 38, type I semi-conductor layer 22 to the active layer 23 to emit light.

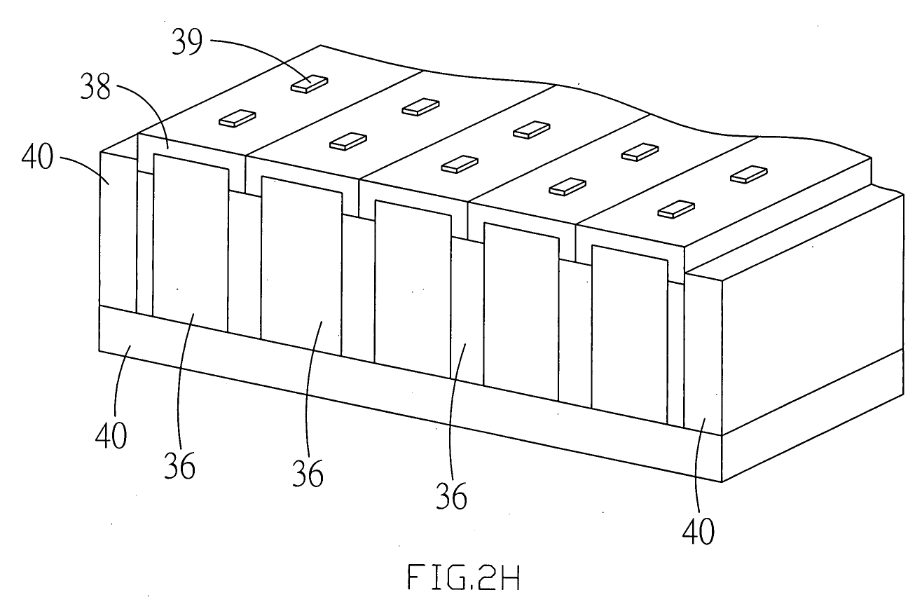

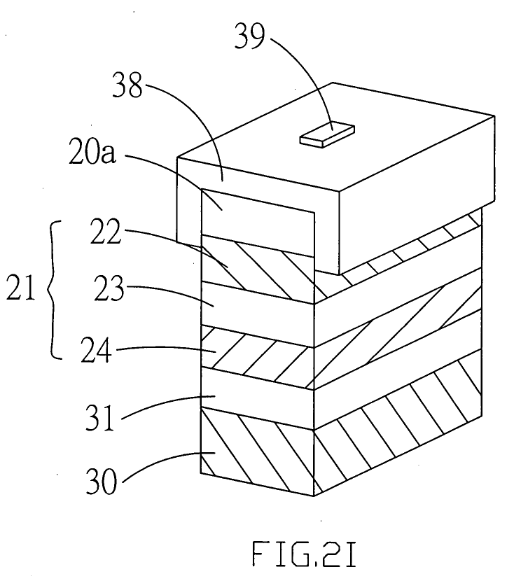

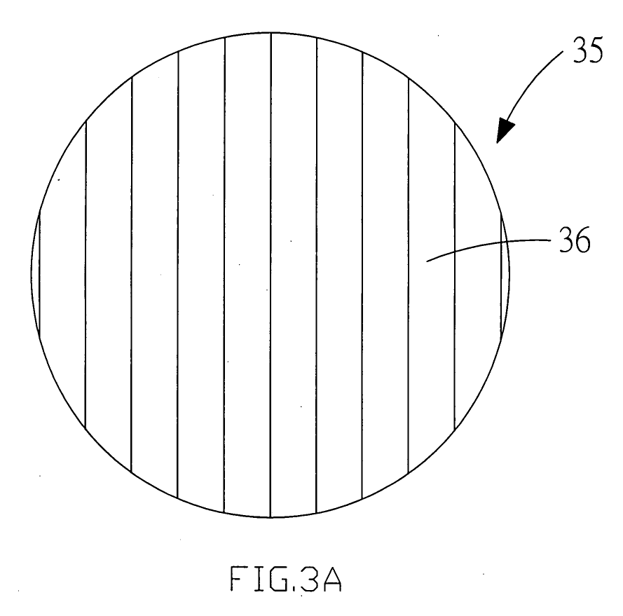

FIGS. 3A˜3B are the second embodying example schematic diagrams of the invention showing the method for manufacturing LED devices. Firstly, as shown in FIG. 3A, the LED wafer 35 is cut to a plurality of LED sticks 36.

As shown in FIG. 3B, each space layer 37 is bonded between every two LED sticks 36 by the bonding method such as glue bonding, whereof material of space layer 37 can be semi-conductor material such as silicon, or ceramic material. Further, the two sides of the space layer 37 can be high reflection treated to form high reflective layers (not shown) which are then bonded with the LED stick, whereof the high reflective layer can be high reflective metal layer or multiple layers of high reflective coating. Material of the high reflective metal layer includes gold, aluminum, silver or one of their alloys to make the LED emit light at the same direction, whereby to increase the directivity of the LED.

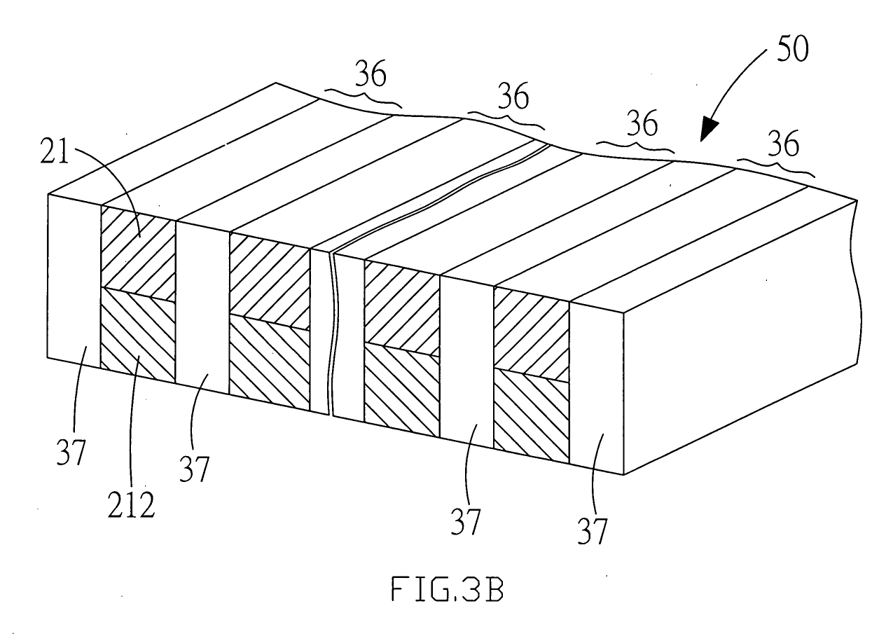

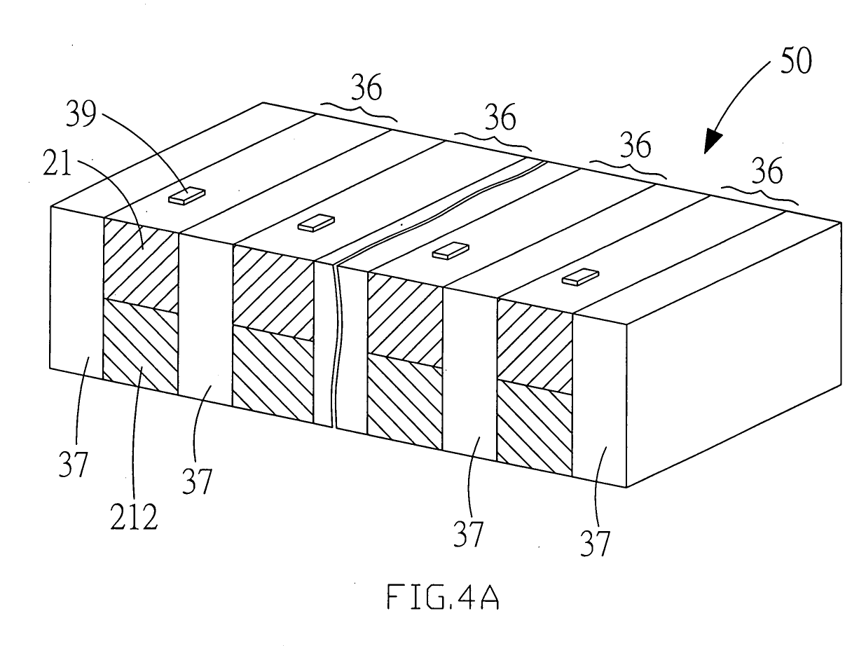

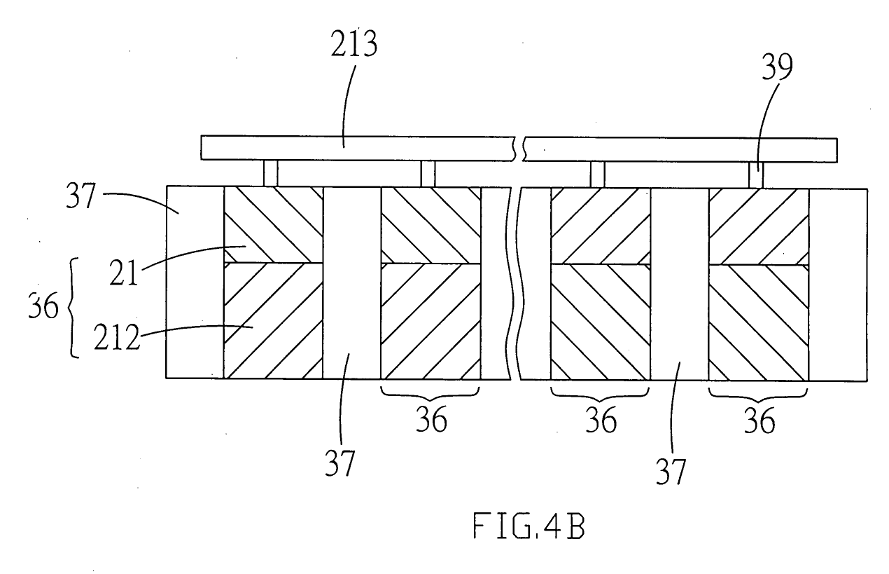

FIGS. 4A˜4B are the embodying example schematic diagrams of the invention showing the method for bonding electrodes on the LED devices. The LED device 50 manufactured by above method is as shown in FIG. 4A, the LED stick 36 is comprised of a LED expitaxial layer 21 and a substrate 212 with a type I electrode 39, whereof the metal bar 213 is bonded with the type I electrode 39 of each LED stick 39 as shown in FIG. 4B (side view) without the need for individual wire bonding.

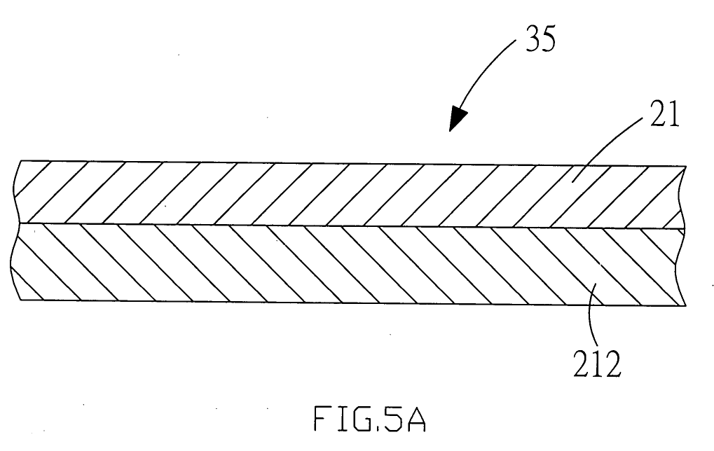

FIGS. 5A˜5C are the third embodying example schematic diagrams of the invention showing the method for manufacturing LED devices. Firstly, as shown in FIG. 5A, a LED wafer 35 has a substrate 212 which includes a LED expitaxial layer 21, whereof the LED expitaxial layer 21 is constituted by a type I semi-conductor layer, an active layer and a type II semi-conductor layer contrary to type I, and the substrate 212 can be a non-conductive substrate or a conductive substrate.

Secondly, the LED wafer 35 is cut to a plurality of LED sticks 36 as shown in FIG. 5B, then a plurality of space layers 37 are provided, each space layer 37 is bonded between every two LED sticks 36, while the height of space layer 37 shall be lower than the height of the LED stick 36 as shown in FIG. 5C. Material of space layer 37 can be semi-conductor material such as silicon, or ceramic material. Further, the row of LED sticks 36 and the space layers 37 are fixed by a fixture 40, then the surface and exposed sides of the LED stick 36 are further manufactured.

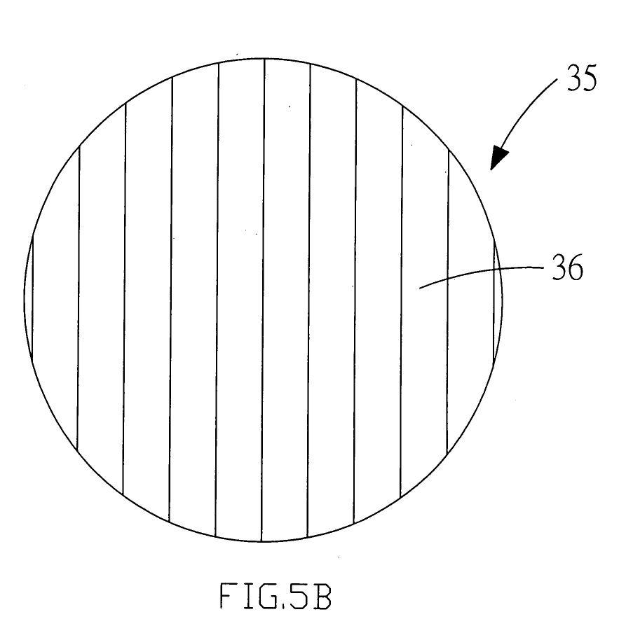

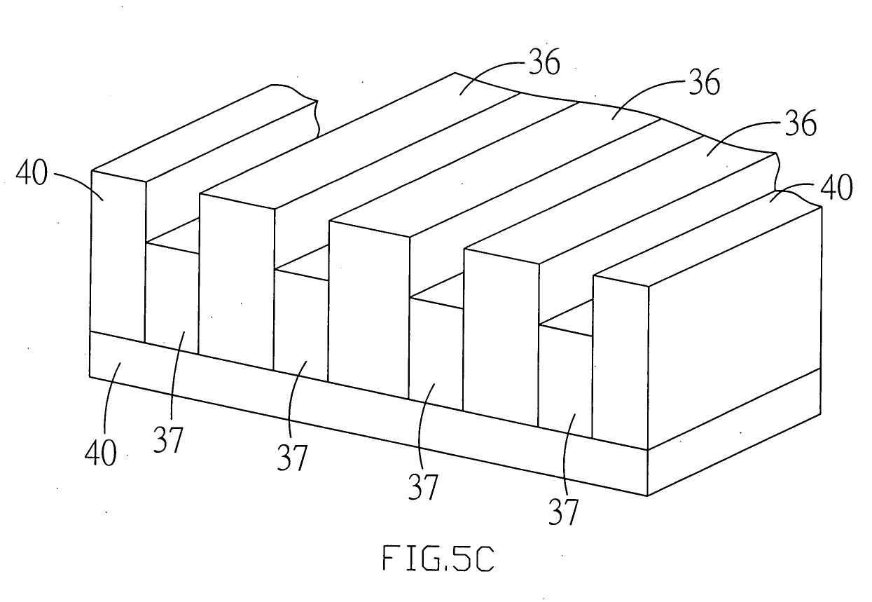

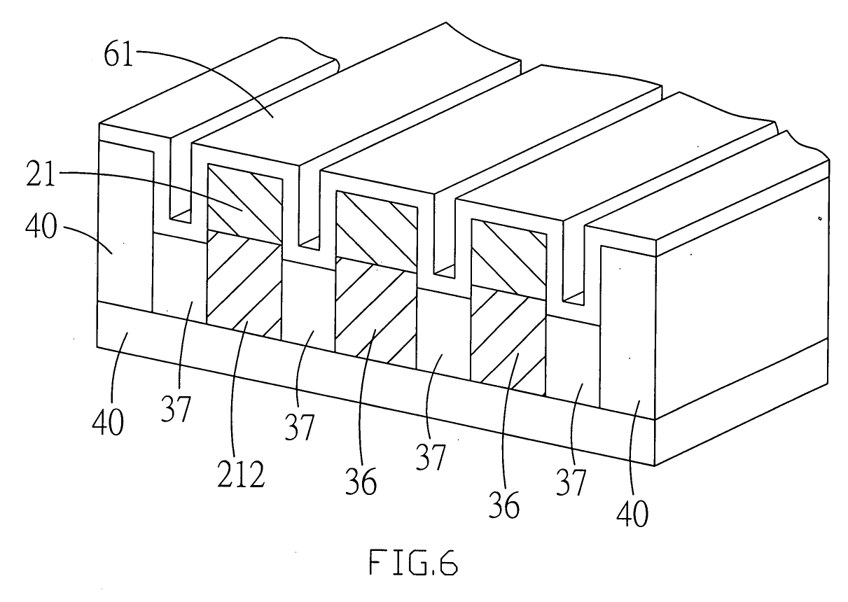

The expose sides and surface of the LED stick is further anti-reflection treated to increase lighting efficiency, whereof the anti-reflection treatment includes surface roughening treatment and anti-reflection coating, so that total reflection of emitting lights of the LED devices can be avoided and the light emitting efficiency can be enhanced to achieve the high efficient LED devices. The exposed sides and surface of the LED stick 36 are anti-reflection coated with a least one anti-reflective layer 61 as shown in the embodying example of FIG. 6, whereof only one anti-reflective layer is shown in the figure. Further, the anti-reflective layer 61 can be dielectric layers of silicon oxide or silicon nitride, and the anti-reflection coating can by done by plasma enhanced chemical vapor deposition (PECVD), etc. whereof the deposition thickness is about one-fourth of the wavelength which is the wavelength of light traveling in the dielectric layer. In general, better effect can be obtained by multiple layers of anti-reflective layers to reduce the total reflection of light source and to increase the lighting efficiency. Thereafter, a plurality of openings can be formed on the electrode (not shown in the figure), and the LED stick is cut to obtain several high efficient LED devices (not shown in the figure).

Through the above said method, the exposed sides of the LED sticks can be high reflection treated to form high reflective layers so that the LED sticks can emit lights at the same direction to increase their light directivities and form the high directive LED sticks (not shown in the figure). Thereof, the high reflective layer is a high reflective metal layer or multiple layers of high reflective coating, when the high reflective layer is a high reflective metal layer, a transparent dielectric layer is formed between the high reflective metal layer and the LED expitaxial layer to avoid short-circuit between the high reflective layer and the LED expitaxial layer.

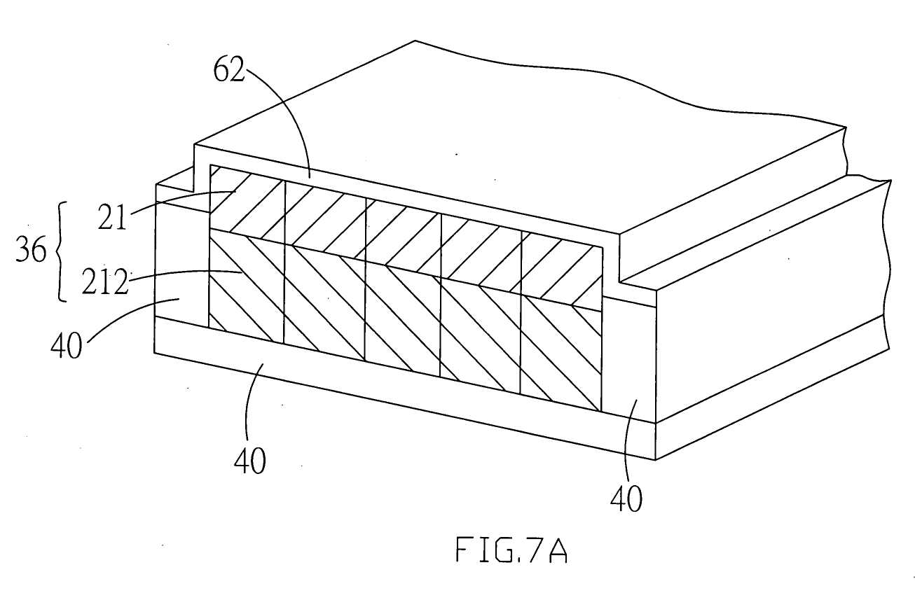

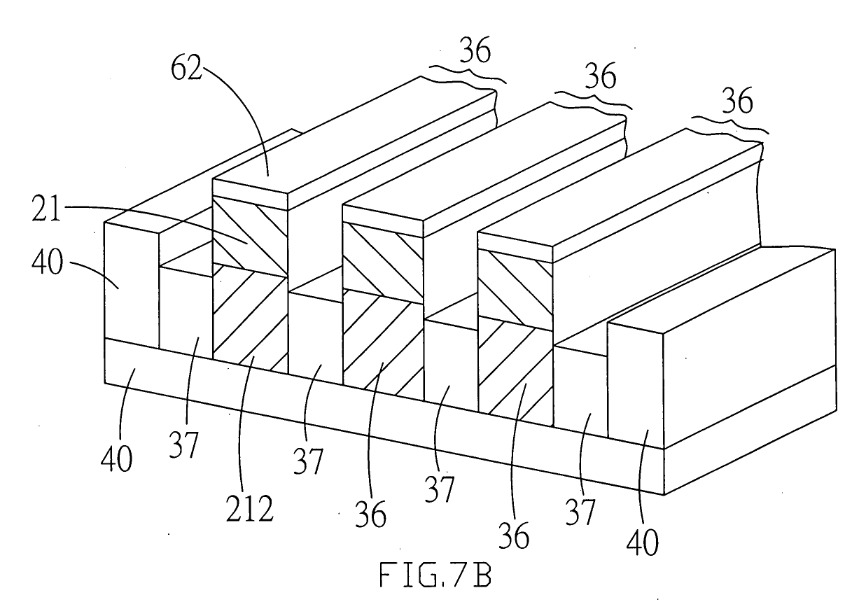

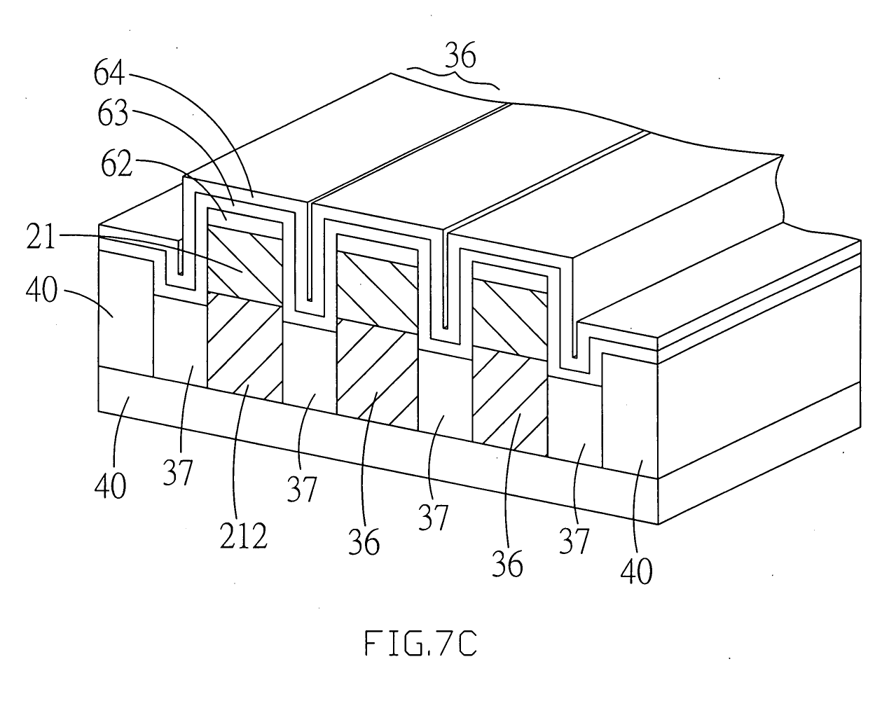

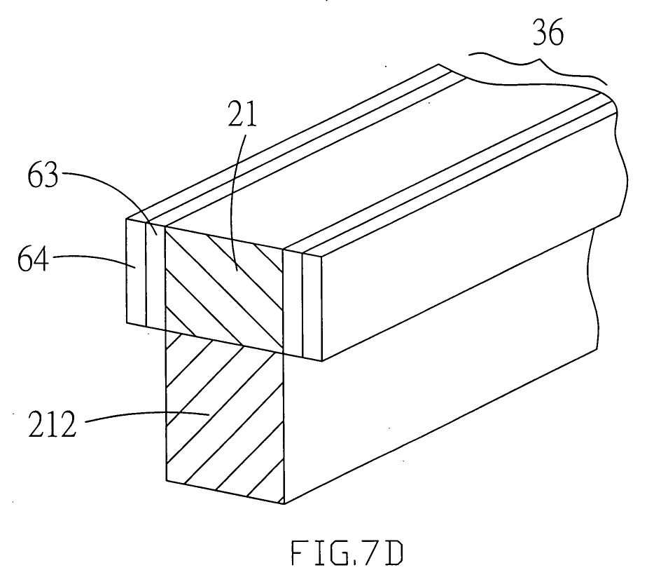

FIGS. 7A˜7D are the embodying example schematic diagrams of the invention showing the method for manufacturing high directive LED devices. Firstly, a LED wafer has a substrate 212 which includes a LED expitaxial layer 21, whereof the embodying example is based on the conductive substrate while the embodying example of non-conductive substrate is not described herein. The LED expitaxial layer 21 is constituted by a type I semi-conductor layer, an active layer and a type II semi-conductor-layer contrary to type I. Secondly, the LED wafer is cut to a plurality of LED sticks 36, and the surface of the said plurality of LED sticks 36 are further formed with an optical resistance layer 62, i.e. as shown in FIG. 7A, a plurality of LED sticks 36 are fixed by a fixture 40 and the said plurality of sticks 36 are rotated to coat with an optical resistance layer 62, after that each of the LED stick 36 are separated.

Next, as shown in FIG. 7B, the said plurality of LED sticks 36 are fixed by a fixture 40, and each space layer 37 is bonded between every two layers of the LED sticks 36, whereof the height of space layer 37 is lower than the height of LED stick 36. Later on, as shown in FIG. 7C, a transparent conductive layer 63 and a high reflective layer 64 are formed on top of the row of plurality of LED sticks and plurality of space layers 37, whereof the high reflective layer 64 is either the high reflective metal layer or the multiple layers of high reflection coating. Material of high reflective metal layers includes gold, aluminum, silver or one of their alloys. The transparent conductive layer 63 is used to avoid short-circuit between the high reflective layer 64 and LED epitaxial layer 21, whereof if the high reflective layer 64 is the multiple layers of high reflection coating, the transparent conductive layer 63 is not needed to be formed. The embodying example diagrams and subsequent descriptions are based on that the high reflective layer 64 is the high reflective metal layer. Afterwards, the space layer 37 is removed, and further the optical resistance layer 62 on the surface of the LED stick 36, transparent conductive layer 63 and the high reflective layer 64 are removed as shown in FIG. 7D. Finally, the electrode is formed on the LED stick 36 (not shown in the figure), and the LED stick is cut to a plurality of LED devices (not shown in the figure).

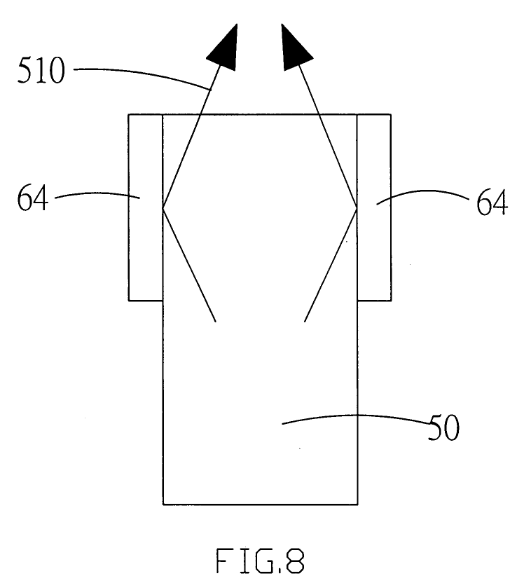

The light 510 emitted by the active layer of LED device 50 is reflected by the high reflective layers 64 at the two sides of the said LED device 50, whereby to render the LED device 50 a characteristic of uniform lighting to emit light at the same direction as shown in FIG. 8.

It is worth to mention that the method of the invention for forming the LED wafer by forming the conductive substrate on the LED expitaxial layer of the non-conductive substrate to form the top and bottom electrodes of the LED devices without the need to remove the non-conductive substrate has avoided damage to the LED expitaxial layer in separating the LED epitaxial layer and non-conductive substrate. As the method of the invention for manufacturing LED devices is by cutting directly to large area LED devices, the yield rate can be increased.

The aforesaid embodiments only described the technical thought and characteristics of the invention. Its main purpose is to make people who is familiar with this art to understand the content of the invention and to carry out accordingly, therefore they shall not be used to limit the range of the claims in the application, i.e all equivalent variations or modifications related to the spirit of the invention shall still be included within the scope of the claims.

1. A method of manufacturing LED devices includes the following steps:
A LED wafer;
The said LED wafer is cut to a plurality of LED sticks; and
The said plurality of LED sticks are fixed by a fixture, whereof each space layer is bonded between every two LED sticks, and the height of the space layer shall be lower than the height of the said LED sticker.
From this, method for manufacturing the surface and exposed sides of the said plurality of LED sticks can be proceeded.

2. The method for manufacturing LED devices as in claim 1, whereof the said LED wafer is a substrate which includes a LED expitaxial layer, whereof the said LED expitaxial layer is comprised of a type I semi-conductor layer, an active layer and a second type semi-conductor layer which is contrary to the type I.

3. The method for manufacturing LED devices as in claim 2, whereof the said substrate is either a conductive or a non-conductive substrate.

4. The method for manufacturing LED devices as in claim 2, whereof the said substrate is a non-conductive substrate and a conductive substrate is further formed on top of the type II semi-conductor layer of the said non-conductive substrate.

5. The method for manufacturing LED devices as in claim 4, whereof the steps to form a conductive substrate on the type II semi-conductor layer of the said non-conductive substrate are: the conductive substrate is either formed by electroplating technology or by bonding.

6. The method for manufacturing LED devices as in claim 1, whereof it includes forming a transparent conductive layer between fixing by a fixture and the manufacturing process on the sides.

7. A method for manufacturing LED devices as in claim 6, whereof the said transparent conductive layer is formed on top of the plurality of LED sticks and plurality of space layers.

8. A method for manufacturing LED devices to increase the lighting efficiencies of the said LED devices, whereof it includes the following steps:
A LED wafer has a substrate which includes a LED expitaxial layer;
The said LED wafer is cut to a plurality of LED sticks;
The said plurality of LED sticks are fixed by a fixture, whereof each space layer is bonded between every two LED sticks, and the height of the space layer shall be lower than the height of the said LED sticker; and
The surface and exposed sides of the said LED stick are anti-reflection treated.

9. The method for manufacturing LED devices as in claim 8, whereof the said LED expitaxial layer includes a type I semi-conductor layer, an active layer and a type II semi-conductor layer contrary to type I.

10. The method for manufacturing LED devices as in claim 9, whereof the said substrate is either conductive substrate or non-conductive substrate.

11. The method for manufacturing LED devices as in claim 9, whereof the said substrate is further comprised of a plurality of electrodes on top of the said LED expitaxial layer.

12. The method for manufacturing LED devices as in claim 8, whereof the said anti-reflection treatment is either surface roughening treatment or anti-reflection coating.

13. The method for manufacturing LED devices as in claim 12, whereof the said anti-reflection coating is formed by applying at least one anti-reflective layer on the surface and exposed sides of the said LED stick.

14. A method for manufacturing LED devices to increase the directivity of the said LED device, whereof it includes the following steps:
A LED wafer has a substrate which includes a LED epitaxial layer;
The said LED wafer is cut to a plurality of LED sticks;
An optical resistance layer is formed on the surfaces of the plurality of LED sticks;
The said plurality of LED sticks are fixed by a fixture, each space layer is bonded between every two LED sticks, whereof the height of the space layer is lower than the height of the LED stick;
A high reflective layer is formed on the whole row of plurality of LED sticks and plurality of space layers; and
The said optical resistance layer and the said high reflective layer on the surface of the plurality of LED sticks are removed,
Thereby, the high reflective layer is formed on the exposed sides of the said plurality of LED sticks.

15. The method for manufacturing LED devices as in claim 14, whereof the said LED epitaxial layer includes a type I semi-conductor layer, an active layer and a type II semi-conductor layer contrary to type I.

16. The method for manufacturing LED devices as in claim 14, whereof the said high reflective layer is a high reflective metal layer.

17. The method for manufacturing LED devices as in claim 16, whereof it further include forming a transparent conductive layer before the step of forming the high reflective layer to avoid short-circuit between the said high reflective layer and the said LED expitaxial layer.

18. The method for manufacturing LED devices as in claim 16, whereof material of the said high reflective metal layer includes gold, aluminum, silver or one of the alloys.

19. The method for manufacturing LED devices as in claim 14, whereof the said high reflective layer is the multiple layers of high reflection coating.

20. The method for manufacturing LED devices as in claim 14, whereof the steps to form the said optical resistance layer is that the said plurality of LED sticks are fixed by a fixture, and the said optical resistance layer is formed on top of the said plurality of LED sticks.
